(19) United States
(12) Patent Application Publication
(10) Pub. No.: US 2022/0064799 A1
(43) Pub. Date: Mar. 3, 2022

(54) VACUUM PROCESSING APPARATUS

(71) Applicant: ULVAC, Inc., Chigasaki-shi (JP)

(72) Inventors: Takehisa MIYAYA, Kanagawa (JP); Yosuke JIMBO, Kanagawa (JP); Yoshiaki YAMAMOTO, Kanagawa (JP); Kenji ETO, Kanagawa (JP); Yoichi ABE, Kanagawa (JP)

(21) Appl. No.: 17/420,087

(22) PCT Filed: Dec. 27, 2019
(86) PCT No.: PCT/JP2019/051352

§ 371 Date: Jun. 30, 2021

(30) Foreign Application Priority Data
Jan. 7, 2019 (JP) 2019-000528

(51) Int. Cl. C23C 16/50; C23C 16/455; H01J 37/32

(52) U.S. Cl. CPC C23C 16/50; C23C 16/45517; H01J 37/32513; H01J 37/3244; H01J 37/32532

(57) ABSTRACT

A vacuum processing apparatus of the present is a vacuum processing apparatus which performs plasma processing. The vacuum processing apparatus includes an electrode flange, a shower plate, an insulating shield, a processing chamber in which a processing-target substrate is to be disposed, an electrode frame, and a slide plate. The electrode frame and the slide plate are slidable in response to thermal deformation that occurs when a temperature of the shower plate is raised or lowered, and a space surrounded by the shower plate, the electrode flange, and the electrode frame is sealable. The electrode frame includes a frame-shaped upper plate surface portion, a vertical plate surface portion, and a lower plate surface portion.

### TECHNICAL FIELD

The present invention relates to a vacuum processing apparatus, and more particularly to a technology thereof suitable for use in performing processing using a plasma.

Priority is claimed on Japanese Patent Application No. 2019-000528 filed in Japan on Jan. 7, 2019, the content of which is incorporated herein by reference.

### BACKGROUND ART

Conventionally, as processing using a plasma, a plasma processing apparatus which performs a surface treatment on a substrate such as film deposition, particularly plasma chemical vapor deposition (CVD), or etching is known. In the plasma processing apparatus, a processing chamber is constituted to include an insulating flange sandwiched between a chamber and an electrode flange such that it has a film deposition space (reaction chamber). In the processing chamber, a shower plate connected to the electrode flange and having a plurality of ejection ports and a heater on which a substrate is disposed are provided.

A space formed between the shower plate and the electrode flange is a gas introduction space into which a source gas is introduced. That is, the shower plate partitions the inside of the processing chamber into a film deposition space in which a film is formed on the substrate and a gas introduction space.

A high-frequency power supply is connected to the electrode flange. The electrode flange and the shower plate function as a cathode electrode.

Patent Documents 1 and 2 describe a configuration in which a circumference of a shower plate is directly connected to an electrode flange.

In such a configuration, since a processing temperature is high during plasma processing, the shower plate thermally expands and then contracts when the temperature is lowered such as at the end of processing.

### PRIOR ART DOCUMENTS

### Patent Documents

[Patent Document 1] PCT International Publication No. WO 2010/079756
[Patent Document 2] PCT International Publication No. WO 2010/079753

### SUMMARY OF THE INVENTION

### Problems to be Solved by the Invention

In recent years, since the size of substrates has come to be large in manufacturing flat panel displays (FPDs) such as liquid crystal displays or organic electroluminescence (EL) displays, a size (area) of a shower plate has also become large. Therefore, when a large area substrate constituting an FPD having a side equal to or larger than 1800 mm or the like is processed, thermal expansion and thermal contraction of a shower plate become extremely large. The thermal expansion and thermal contraction of the shower plate may reach several cm to tens of cm at corner portions of the substrate.

However, conventional technologies do not pay attention to a problem caused by thermal expansion and thermal contraction of the shower plate, and there have been cases in which the number of times a member supporting the shower plate can be used is reduced. Particularly, when deformation of the member is significant, there has been a problem in that the member has had to be disposed of each time maintenance work is performed.

Also, the member supporting the shower plate may be rubbed according to the thermal expansion and thermal contraction of the shower plate, and particles or the like may be generated due to scratching of the member. This becomes a cause of generation of defects in plasma processing, and there is a demand to solve the problem.

Also, in the conventional technology, a problem in that a gas leaking to a side outward from a circumferential edge of the shower plate reaches a space facing a processing-target substrate is not described, but there is a demand to solve this problem.

Furthermore, conventionally, a temperature of a shower plate has been approximately 200° C. to 325° C., but along with an increase in plasma processing temperature, in recent years, there has come to be demand for an apparatus capable of performing plasma processing at a processing temperature such that a temperature of the shower plate exceeds 400° C.

Also, when a temperature distribution of the shower plate deteriorates such that a temperature distribution of the shower plate is not uniform or an in-plane temperature difference is increased, film deposition characteristics are deteriorated. Therefore, there is a demand for improving a temperature distribution of the shower plate.

The present invention has been made in view showing the above circumstances and is intended to achieve the following objectives.

1. Improving sealing of a gas for preventing gas leakage from around a shower plate.

2. Providing a processing apparatus that solves a problem caused by thermal expansion and contraction of the shower plate having a large area.

3. Providing a processing apparatus capable of allowing an increase in processing temperature in a processing apparatus which performs processing such that a temperature of the shower plate exceeds 400° C.

4. Improving a temperature distribution in the shower plate.

### Means for Solving the Problems

A vacuum processing apparatus of the present invention is a vacuum processing apparatus which performs plasma processing and includes an electrode flange connected to a high-frequency power supply, a shower plate spaced apart from and facing the electrode flange and serving as a cathode together with the electrode flange, an insulating shield provided around the shower plate, a processing chamber in which a processing-target substrate is to be disposed in an opposite side of the shower plate opposite with respect to the electrode flange, an electrode frame attached to the shower plate side of the electrode flange, and a slide plate attached to a circumferential edge portion of the shower plate on the electrode frame side, in which the shower plate is formed to have a substantially rectangular outline, the electrode frame and the slide plate are slidable in response to thermal deformation that occurs when a temperature of the shower plate is raised or lowered, and a space surrounded by the shower plate, the electrode flange, and the electrode frame is sealable, and the electrode frame includes a frame-shaped upper plate surface portion attached to the electrode flange, a vertical plate surface portion provided to stand toward the shower plate from an entire outer circumference of an outline of the upper plate surface portion, and a lower plate surface portion extending substantially parallel to the upper plate surface portion from a lower end of the vertical plate surface portion toward an inner end of the outline of the upper plate surface portion. Therefore, the above-described problems were solved.

In the vacuum processing apparatus of the present invention, the slide plate may have a recessed groove formed at a portion in contact with the shower plate.

In the present invention, the slide plate may include a side slide portion corresponding to a side of the shower plate having a substantially rectangular outline, and a corner slide portion corresponding to a corner of the shower plate, the side slide portion and the corner slide portion may be in contact with each other via a sliding seal surface which is parallel to the side of the shower plate, and the side slide portion and the corner slide portion may be slidable via the sliding seal surface in response to thermal deformation that occurs when a temperature of the shower plate is raised or lowered while a sealed state is maintained.

In the vacuum processing apparatus of the present invention, an upper end of the sliding seal surface may be in contact with the electrode frame and a lower end of the sliding seal surface may be in contact with the shower plate in the side slide portion and the corner slide portion.

In the present invention, a plate-shaped reflector along an entire circumference of the electrode frame may be provided on an inner circumferential side of the electrode frame, an upper end of the reflector may be attached to the electrode flange, and a lower end of the reflector may be positioned close to an inner end of the lower plate surface portion.

In the vacuum processing apparatus of the present invention, the shower plate may be supported by the electrode frame using a support member penetrating through an elongated hole provided in the shower plate, and the elongated hole may be formed to be longer in a direction of thermal deformation that occurs when a temperature of the shower plate is raised or lowered so that the support member is slidable in response to the thermal deformation that occurs when a temperature of the shower plate is raised or lowered.

In the vacuum processing apparatus of the present invention, a gap which allows the shower plate to be thermally expandable may be provided between circumferential end surfaces of the shower plate and the slide plate, and the insulating shield.

A vacuum processing apparatus of the present invention is a vacuum processing apparatus which performs plasma processing and includes an electrode flange connected to a high-frequency power supply, a shower plate spaced apart from and facing the electrode flange and serving as a cathode together with the electrode flange, an insulating shield provided around the shower plate, a processing chamber in which a processing-target substrate is to be disposed in an opposite side of the shower plate opposite with respect to the electrode flange, an electrode frame attached to the shower plate side of the electrode flange, and a slide plate attached to a circumferential edge portion of the shower plate on the electrode frame side, in which the shower plate is formed to have a substantially rectangular outline, the electrode frame and the slide plate are slidable in response to thermal deformation that occurs when a temperature of the shower plate is raised or lowered, and a space surrounded by the shower plate, the electrode flange, and the electrode frame is sealable, and the electrode frame includes a frame-shaped upper plate surface portion attached to the electrode flange, a vertical plate surface portion provided to stand toward the shower plate from an entire outer circumference of an outline of the upper plate surface portion, and a lower plate surface portion extending substantially parallel to the upper plate surface portion from a lower end of the vertical plate surface portion toward an inner end of the outline of the upper plate surface portion.

Also, with the configuration described above, the slide plate and the electrode frame can slide with each other. Therefore, when the outline of the shower plate is expanded by thermal expansion or the outline of the shower plate is contracted by thermal contraction, deformation between the electrode frame connected to the electrode flange on a low temperature side and the shower plate on a high temperature side can be absorbed by sliding of the slide plate with respect to the electrode frame.

In other words, deformation in which lengths of the shower plate expand due to the slide plate sliding with respect to the electrode frame when thermal deformation, particularly thermal expansion occurs at the time of a temperature rise of the shower plate is absorbed by the sliding of the slide plate with respect to the electrode frame without affecting the electrode frame, the electrode flange, and the insulating shield.

Therefore, stress applied by the thermal expansion of the shower plates is reduced in portions from the shower plate to the slide plate, the electrode frame, and the electrode flange which are connected in a stacked state.

Therefore, generation of deformation in components can be prevented.

At the same time, the slide plate slides at the time of thermal expansion of the shower plate, and therefore a sealed state in a space surrounded by the shower plate, the slide plate, the electrode frame, and the electrode flange can be maintained, and occurrence of seal failure can be prevented.

At the same time, the vertical plate surface portion of the electrode frame serves as a heat transfer path in a heat flow path from the shower plate on a high temperature side to the electrode flange on a low temperature side. The vertical plate surface portion is literally a plate body provided to stand between the shower plate and the electrode flange in a direction in which the shower plate and the electrode flange face each other. In the vertical plate surface portion of the electrode frame, a cross-sectional area thereof serving as the heat transfer path can be made extremely small.

Therefore, the heat transfer path from the shower plate to the electrode flange is the same as a cross section of the vertical plate surface portion. Therefore, a cross-sectional area of the heat transfer path can be reduced compared to a case of a bulk member, and thus a heat flow rate transferred from the shower plate to the electrode flange can be reduced.

Therefore, a temperature drop in a region close to an edge portion of the shower plate can be prevented during plasma processing, and a temperature distribution in the shower plate during the plasma processing can be made uniform.

Furthermore, deformation in which lengths of the shower plate contract due to the slide plate sliding with respect to the electrode frame when shrinkage occurs in the shower plate, which has been thermally expanded, at the time of a temperature drop is absorbed by the sliding of the slide plate with respect to the electrode frame without affecting the electrode frame, the electrode flange, and the insulating shield.

Therefore, stress applied by the thermal contraction of the shower plates is reduced in the portions from the shower plate to the slide plate, the electrode frame, and the electrode flange which are connected in a stacked state.

Therefore, generation of deformation in components can be prevented.

At the same time, the slide plate slides at the time of thermal contraction of the shower plate, and therefore a sealed state in the space surrounded by the shower plate, the slide plate, the electrode frame, and the electrode flange can be maintained, and occurrence of seal failure can be prevented.

Here, “sealed state in the space surrounded by the shower plate, the slide plate, the electrode frame, and the electrode flange” indicates that a source gas supplied to the space leaks along a path other than a path in which the source gas moves through a large number of through holes formed in the shower plate toward a side of a processing-target substrate.

In the vacuum processing apparatus of the present invention, the slide plate has a recessed groove formed at a portion in contact with the shower plate.

Therefore, the slide plate is in contact with the shower plate on both sides of the recessed groove. That is, an area of the slide plate in contact with the shower plate can be set to be smaller than an area thereof in a plan view. Therefore, in the heat flow path from the shower plate on a high temperature side to the electrode flange on a low temperature side, a cross-sectional area serving as a heat transfer path in the slide plate portion can be made extremely small.

Therefore, an amount of heat that escapes from the shower plate to the electrode flange via the slide plate can be made small. Therefore, a temperature drop in a region close to the edge portion of the shower plate during plasma processing can be prevented. Therefore, a temperature distribution in the shower plate during the plasma processing can be made uniform.

In the present invention, the slide plate includes a side slide portion corresponding to a side (outline side) of the shower plate having a substantially rectangular outline, and a corner slide portion corresponding to a corner of the shower plate, the side slide portion and the corner slide portion are in contact with each other via a sliding seal surface which is parallel to the side of the shower plate, and the side slide portion and the corner slide portion are slidable via the sliding seal surface in response to thermal deformation that occurs when a temperature of the shower plate is raised or lowered while a sealed state is maintained.

Therefore, even when thermal deformation occurs in the shower plate when a temperature of the shower plate is raised or lowered, the sealed state in the slide plate can be maintained.

When thermal deformation, particularly thermal expansion occurs at the time of a temperature rise of the shower plate, the side slide portion of the slide plate slides with respect to the corner slide portion positioned at a corner portion of the shower plate.

At this time, the side slide portion and the corner slide portion slide to be separated from each other. Also, the sliding seal surface of the side slide portion and the sliding seal surface of the corner slide portion slide while maintaining a state of being in contact with each other.

Therefore, the deformation in which lengths of the outline sides of the shower plate expand is absorbed by the sliding of the slide plate with respect to the electrode frame without affecting the electrode frame, the electrode flange, and the insulating shield. Therefore, stress applied to the slide plate due to the thermal expansion of the shower plate is reduced.

Therefore, generation of deformation in the slide plate can be prevented.

At the same time, the side slide portion of the slide plate slides with respect to the corner slide portion, and therefore a sealed state in the space surrounded by the shower plate, the slide plate, the electrode frame, and the electrode flange can be maintained at the time of thermal expansion.

Also, when shrinkage occurs in the shower plate, which has been thermally expanded, at the time of a temperature drop of the shower plate, the side slide portion of the slide plate slides with respect to the corner slide portion positioned at the corner portion of the shower plate. At this time, the side slide portion and the corner slide portion slide to approach each other. Also, the sliding seal surface of the side slide portion and the sliding seal surface of the corner slide portion slide while maintaining a state of being in contact with each other.

Therefore, the deformation in which a length of the shower plate contracts is absorbed by the sliding of the slide plate with respect to the electrode frame without affecting the electrode frame, the electrode flange, and the insulating shield. Therefore, stress applied to the slide plate due to the thermal contraction of the shower plate is reduced.

Therefore, generation of deformation in the slide plate can be prevented.

At the same time, the side slide portion of the slide plate slides with respect to the corner slide portion, and therefore a sealed state in the space surrounded by the shower plate, the slide plate, the electrode frame, and the electrode flange can be maintained at the time of thermal contraction.

At this time, the sliding seal surface of the side slide portion and the sliding seal surface of the corner slide portion form a sealed state as a so-called labyrinth structure.

Furthermore, the side slide portion is disposed corresponding to four sides of the shower plate having a rectangular outline shape, and the side slide portions and the corner slide portions slide with each other on the sliding seal surfaces. Therefore, even when a relative position between the electrode flange and the shower plate outline is changed, the sealed state can be maintained.

In the vacuum processing apparatus of the present invention, an upper end of the sliding seal surface is in contact with the electrode frame and a lower end of the sliding seal surface is in contact with the shower plate in the side slide portion and the corner slide portion.

Therefore, the side slide portion and the corner slide portion in which the sliding seal surfaces are in contact with each other are slidable in a side direction of the outline of the slide plate over a distance between the electrode frame and the shower plate, that is, the entire length in a thickness direction of the slide plate.

Therefore, both the deformation in which lengths of the shower plate expand and the deformation in which lengths of the shower plate contracts are absorbed by the sliding of the slide plate with respect to the electrode frame without affecting the electrode frame, the electrode flange, and the insulating shield. At the same time, the sealed state can be maintained.

In the present invention, a plate-shaped reflector along an entire circumference of the electrode frame is provided on an inner circumferential side of the electrode frame, an upper end of the reflector is attached to the electrode flange, and a lower end of the reflector is positioned close to an inner end of the lower plate surface portion.

Therefore, an amount of transferred heat radiated from the shower plate to the internal space of the electrode frame formed by the upper plate surface portion, the vertical plate surface portion, and the lower plate surface portion is reduced. At the same time, an amount of source gas entering the internal space of the electrode frame formed by the upper plate surface portion, the vertical plate surface portion, and the lower plate surface portion can be reduced.

Here, “the lower end of the reflector being positioned close to an inner end of the lower plate surface portion” indicates such an extent that an opening portion of the internal space of the electrode frame formed by the upper plate surface portion, the vertical plate surface portion, and the lower plate surface portion is hidden by the reflector and is not visually recognized when the electrode frame is viewed from a center of the space surrounded by the shower plate, the slide plate, the electrode frame, and the electrode flange.

Furthermore, the lower end of the reflector and the inner end of the lower plate surface portion are in a state of being spaced apart from each other and are in a state in which a source gas does not actively enter the opening portion of the internal space of the electrode frame. The lower end of the reflector and the inner end of the lower plate surface portion are not in contact with each other and are not in a sealed state.

In the vacuum processing apparatus of the present invention, the shower plate is supported by the electrode frame using a support member penetrating through an elongated hole provided in the shower plate, and the elongated hole is formed to be longer in a direction of thermal deformation that occurs when a temperature of the shower plate is raised or lowered so that the support member is slidable in response to the thermal deformation that occurs when a temperature of the shower plate is raised or lowered.

Therefore, when the support member relatively moves in a major axis direction of the elongated hole, the support member can relatively move without being hindered by the elongated hole. Therefore, when the shower plate is thermally deformed with respect to the support member fixed to the electrode frame, relative movement of the supporting position of the support member in the slide plate and the shower plate in response to the deformation is not hindered.

In other words, when thermal deformation, that is, thermal expansion occurs at the time of a temperature rise of the shower plate, an amount of deformation in a region including the corner portion of the shower plate becomes the largest. At this time, the corner portion of the shower plate is deformed such that it moves (expands) outward in a radial direction from a center position of the shower plate toward an outer outline edge portion. On the other hand, since the support member is fixed to the electrode frame, the support member does not follow the movement deformation of the edge portion of the shower plate.

However, since the elongated hole is formed to be longer in the direction of thermal deformation of the shower plate, a relative position of the support member is movable in the elongated hole. In the elongated hole, the support member relatively moves in a direction opposite to the direction of thermal deformation of the shower plate, that is from a position on an outward side of the edge portion of the shower plate toward a position on a center side thereof. Therefore, the slide plate and the shower plate are slidable while maintaining a support state with respect to the electrode frame.

Accordingly, the deformation in which outline lengths of the shower plate expand is absorbed without affecting the electrode frame, the electrode flange, and the insulating shield. At the same time, the support state of the slide plate and the shower plate with respect to the electrode frame can be maintained.

Also, when shrinkage occurs in the shower plate, which has been thermally expanded, at the time of a temperature drop of the shower plate, an amount of deformation in a region close to the corner portion of the shower plate becomes the largest. At this time, the corner portion of the shower plate is deformed such that it moves (contracts) inward in a radial direction from the outer outline edge portion of the shower plate toward the center position thereof. On the other hand, since the support member is fixed to the electrode frame, the support member does not follow the movement deformation of the shower plate.

However, since the elongated hole is formed to be longer in the direction of thermal deformation of the shower plate, a relative position of the support member is movable in the elongated hole. The support member relatively moves in the elongated hole from the center side of the shower plate toward an outer edge portion side thereof. Therefore, the slide plate and the shower plate are slidable while maintaining the support state with respect to the electrode frame.

Therefore, the deformation in which a length of the shower plate contracts is absorbed without affecting the electrode frame, the electrode flange, and the insulating shield. At the same time, the support state of the slide portion plate and the shower plate with respect to the electrode frame can be maintained.

Therefore, the electrode flange and the shower plate can be electrically connected by the electrode frame and the slide plate which are maintained in contact with each other by the support member. Furthermore, the slide plate and the electrode frame can move relative positions of the electrode flange and the outline of the shower plate by sliding with each other on the sliding seal surfaces while a sealed state is maintained.

In the vacuum processing apparatus of the present invention, a gap which allows the shower plate to be thermally expandable is provided between circumferential end surfaces of the shower plate and the slide plate, and the insulating shield.

Therefore, when the shower plate thermally expands, expansion deformation of the shower plate is absorbed in the gap, and a sealed state can be maintained without generating unnecessary stress in each member.

### Effects of the Invention

According to the present invention, effects can be achieved such that it is possible to provide a processing apparatus in which generation of deformation in components due to thermal deformation of the shower plate caused by increase and decrease in temperature according to processing of the vacuum processing apparatus can be prevented, generation of particles can be reduced, problems caused by thermal deformation of the shower plate having a large area can be solved, improvement in sealing of a gas around the shower plate is achieved, and an increase in processing temperature such that a temperature of a shower plate exceeds 400° C. can be allowed.

### BRIEF DESCRIPTION OF THE DRAWINGS

FIG. 1 is a schematic cross-sectional view showing a vacuum processing apparatus according to a first embodiment of the present invention.

FIG. 2 is a top view showing a shower plate in the vacuum processing apparatus according to the first embodiment of the present invention.

FIG. 3 is an enlarged cross-sectional view showing an electrode frame, a slide plate, and a circumferential edge portion of the shower plate in the vacuum processing apparatus according to the first embodiment of the present invention.

FIG. 4 is a top view showing a region including a corner portion of the electrode frame in the vacuum processing apparatus according to the first embodiment of the present invention.

FIG. 5 is a partial perspective view showing a lower surface side of a region including a corner portion of the slide plate in the vacuum processing apparatus according to the first embodiment of the present invention.

FIG. 6 is a bottom view showing a vicinity of a region including a circumferential edge portion of the slide plate in the vacuum processing apparatus according to the first embodiment of the present invention.

FIG. 7 is a cross-sectional view showing a thermally expanded state of the electrode frame, the slide plate, and a circumferential edge portion of the shower plate in the vacuum processing apparatus according to the first embodiment of the present invention.

FIG. 8 is a bottom view showing a thermally expanded state of a region close to a circumferential edge portion of the slide plate in the vacuum processing apparatus according to the first embodiment of the present invention.

FIG. 9 is a plan view showing a temperature distribution of a quarter of the slide plate in an experimental example according to the present invention.

FIG. 10 is a plan view showing a temperature distribution of a quarter of a slide plate in an experimental example according to the present invention.

FIG. 11 is a bottom view showing another example of a region including a circumferential edge portion of the slide plate in the vacuum processing apparatus according to the first embodiment of the present invention.

### EMBODIMENTS FOR CARRYING OUT THE INVENTION

Hereinafter, a vacuum processing apparatus according to a first embodiment of the present invention will be described with reference to the drawings.

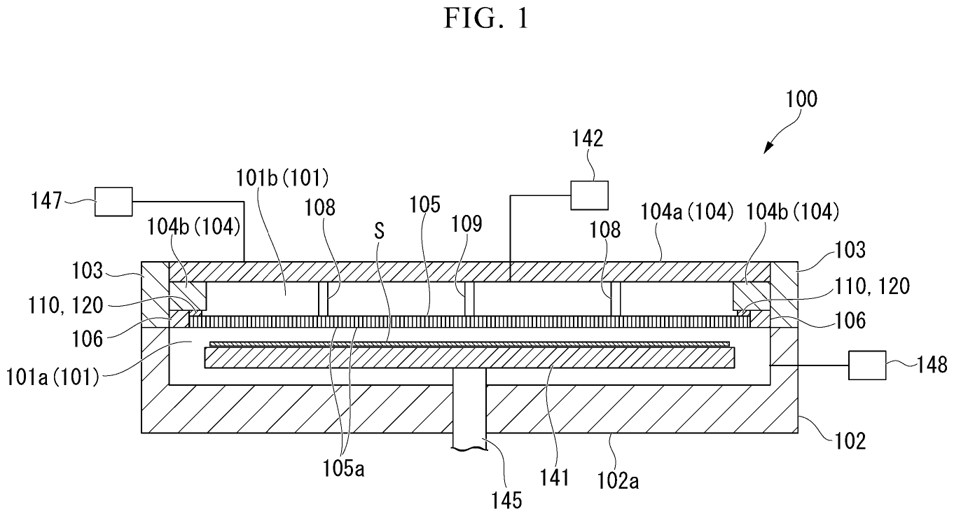

FIG. 1 is a schematic cross-sectional view showing a vacuum processing apparatus of the present embodiment, and reference numeral 100 in FIG. 1 indicates a vacuum processing apparatus.

In the present embodiment, a film deposition apparatus using a plasma chemical vapor deposition (CVD) method as plasma processing will be described.

The vacuum processing apparatus 100 according to the present embodiment performs film deposition on a substrate (processing-target substrate) S using a plasma CVD method.

As shown in FIG. 1, the vacuum processing apparatus 100 according to the present embodiment includes a processing chamber 101 having a film deposition space 101a serving as a reaction chamber. The processing chamber 101 is constituted by a vacuum chamber 102 (chamber), an electrode flange 104, and an insulating flange 103 sandwiched between the vacuum chamber 102 and the electrode flange 104.

An opening is formed at a bottom portion 102a (inner bottom surface) of the vacuum chamber 102. A support column 145 is inserted through the opening, and the support column 145 is disposed at a lower portion of the vacuum chamber 102. A plate-shaped support portion (heater) 141 is connected to a distal end (in the vacuum chamber 102) of the support column 145.

Also, a vacuum pump (evacuation means) 148 is provided for the vacuum chamber 102 via an evacuation pipe. The vacuum pump 148 depressurizes the vacuum chamber 102 so that the inside of the vacuum chamber 102 reaches a vacuum state.

Also, the support column 145 is connected to a lifting mechanism (not shown in drawings) provided outside the vacuum chamber 102 and is vertically movable in a vertical direction with respect to the substrate S.

The electrode flange 104 includes an upper wall 104a and a circumferential wall 104b. The electrode flange 104 is disposed such that an opening of the electrode flange 104 is positioned on a downward side in the vertical direction with respect to the substrate S. Also, a shower plate 105 is attached in the opening of the electrode flange 104.

Therefore, a space 101b (gas introduction space) is formed between the electrode flange 104 and the shower plate 105. Also, the upper wall 104a of the electrode flange 104 faces the shower plate 105. A gas supply unit 142 (gas supply means) is connected to the upper wall 104a via a gas introduction port.

The space 101b functions as a gas introduction space into which a process gas is introduced from the gas supply unit 142.

The electrode flange 104 and the shower plate 105 are formed of a conductive material and are made of a metal such as, for example, aluminum.

A shield cover is provided around the electrode flange 104 to cover the electrode flange 104. The shield cover is not in contact with the electrode flange 104 and is disposed to be continuous with a circumferential edge portion of the vacuum chamber 102.

Also, a radio frequency (RF) power supply 147 (high-frequency power supply) provided outside the vacuum chamber 102 is connected to the electrode flange 104 via a matching box. The matching box is attached to the shield cover and the vacuum chamber 102 is grounded via the shield cover.

The electrode flange 104 and the shower plate 105 are configured as a cathode electrode. A plurality of gas ejection ports 105a are formed in the shower plate 105. A process gas introduced into the space 101b is ejected from the gas ejection ports 105a to the film deposition space 101a in the vacuum chamber 102.

At the same time, the electrode flange 104 and the shower plate 105 that are supplied with power from the RF power supply 147 serve as a cathode electrode, and a plasma is generated in the film deposition space 101a to perform processing such as film deposition.

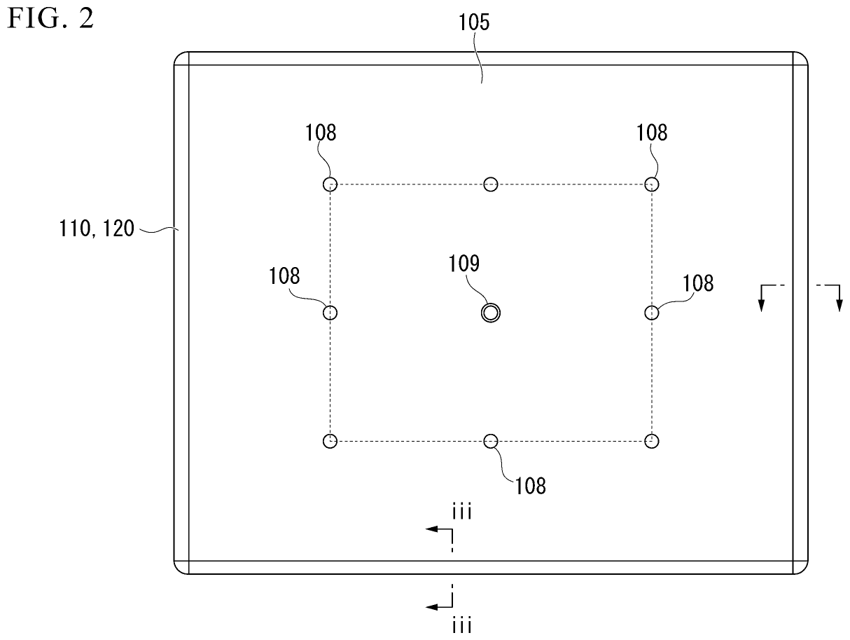

FIG. 2 is a top view showing the shower plate 105 in the present embodiment in a plan view.

The shower plate 105 is supported to be suspended downward from the electrode flange 104 by a rod-shaped fixed shaft 109 and movable shafts 108.

The fixed shaft 109 is fixedly attached to a center position of the shower plate 105 in a plan view. The movable shafts 108 are disposed at vertexes and midpoints of four sides of a rectangle with the fixed shaft 109 as a center.

Unlike the fixed shaft 109, the movable shafts 108 have a structure that moves in response to thermal expansion of the shower plate 105. Specifically, the movable shafts 108 are connected to the shower plate 105 via spherical bushes provided at lower ends of the movable shafts 108. The movable shafts 108 can support the shower plate 105 while moving in accordance with deformation of the shower plate 105 in a horizontal direction.

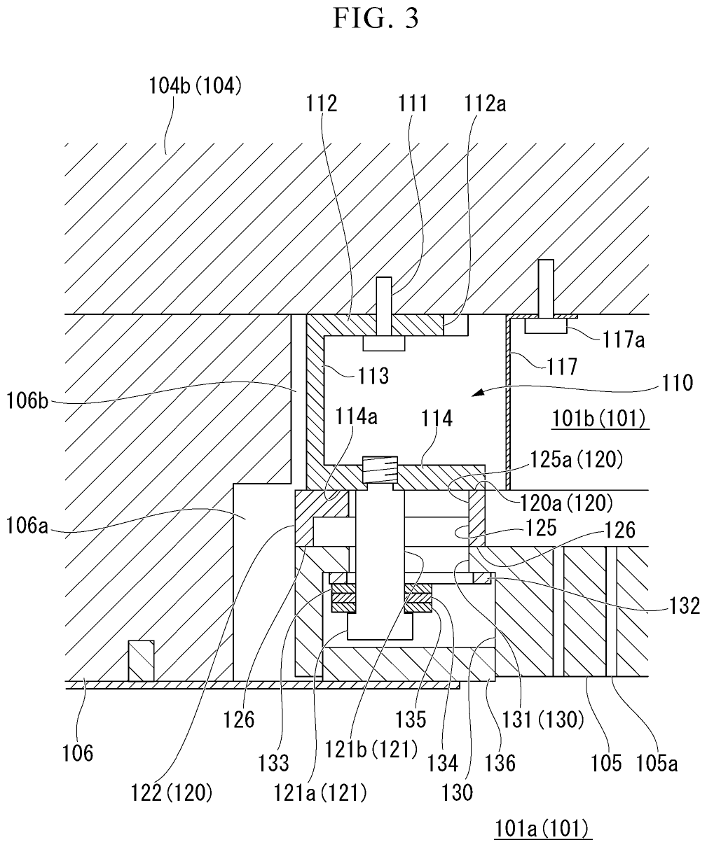

FIG. 3 is an enlarged cross-sectional view showing a region including an edge portion of the shower plate 105 according to the present embodiment.

An insulating shield 106 is circumferentially provided at an outer position of a circumferential edge portion of the shower plate 105 to be spaced apart from the edge portion of the shower plate 105. The insulating shield 106 is attached to the circumferential wall 104b of the electrode flange 104. A thermal expansion absorption space (gap) 106a is formed at an inner position of the insulating shield 106 and an outer position of a circumferential end surface of the shower plate 105.

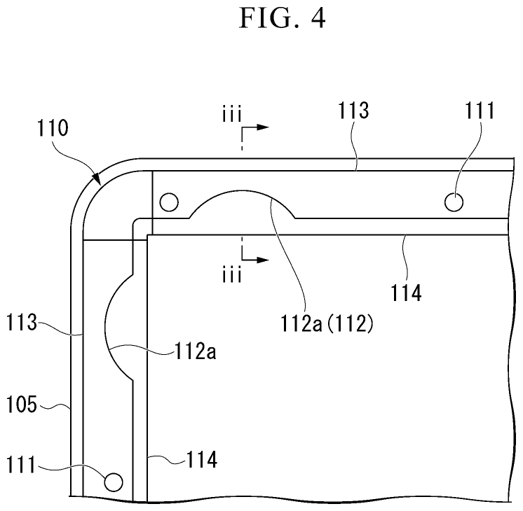

FIG. 4 is an enlarged top view showing a region including a corner portion of an electrode frame 110 in the present embodiment.

As shown in FIGS. 3 and 4, the electrode frame 110 and a slide plate 120 are circumferentially provided on an upper side of the circumferential edge portion of the shower plate 105.

As shown in FIGS. 3 and 4, the electrode frame 110 is attached to a lower side of the circumferential wall 104b of the electrode flange 104 using a support member 111 such as a bolt. The electrode frame 110 is circumferentially provided at a position inside the insulating shield 106. The electrode frame 110 is circumferentially provided at a position corresponding to an outer outline of the gas introduction space 101b in a plan view.

As shown in FIGS. 2 and 3, the slide plate 120 is circumferentially provided in the circumferential edge portion of the shower plate 105 to substantially overlap the electrode frame 110 in a plan view. The slide plate 120 is attached to the shower plate 105. The shower plate 105 and the electrode frame 110 are slidable with each other

The edge portion of the shower plate 105 is supported to be suspended by the electrode frame 110 using a stepped bolt (support member) 121.

The stepped bolt 121 penetrates through the shower plate 105 and the slide plate 120 from below, and a distal end thereof is fastened to the electrode frame 110.

The slide plate 120 is positioned between the electrode frame 110 and the shower plate 105. The slide plate 120 is movable in a direction parallel to a surface of the shower plate 105 integrally with the edge portion of the shower plate 105 in response to thermal deformation that occurs when a temperature of the shower plate 105 is raised or lowered.

As shown in FIGS. 1 to 4, the electrode frame 110 allows the slide plate 120 to be slid and moved so that a slide position thereof changes in response to thermal deformation of the shower plate 105 that occurs when a temperature of the shower plate 105 is raised or lowered.

The electrode frame 110 and the slide plate 120 serve as a sealing side wall of the gas introduction space 101b surrounded by the shower plate 105 and the electrode flange 104.

As shown in FIG. 3, even when the slide plate 120 attached to the shower plate 105 and the electrode frame 110 attached to the electrode flange 104 corresponding to the slide plate 120 slide, the electrode frame 110 and the slide plate 120 are maintained in a state of being in contact with each other.

Therefore, the electrode frame 110 and the slide plate 120 can seal the gas introduction space 101b even when they slide with each other.

The electrode frame 110 and the slide plate 120 electrically connect the circumferential edge portion of the shower plate 105 to the electrode flange 104.

As shown in FIG. 2, the electrode frame 110 has a rectangular outline that is substantially the same outer outline as the circumferential edge portion of the shower plate 105 in a plan view. Also, the electrode frame 110 has substantially the same width around the shower plate 105. The electrode frame 110 is made of a metal such as, for example, Hastelloy (registered trademark).

As shown in FIG. 2, similarly to the electrode frame 110, the slide plate 120 has a rectangular outline that is substantially the same outer outline as the circumferential edge portion of the shower plate 105 in a plan view. Also, the slide plate 120 has substantially the same width around the shower plate 105. The slide plate 120 may be made of the same material as the electrode frame 110, for example, a metal such as Hastelloy.

As shown in FIGS. 3 and 4, the electrode frame 110 includes an upper plate surface portion (fixed portion) 112, a vertical plate surface portion (wall portion) 113, and a lower plate surface portion (base portion) 114.

The upper plate surface portion (fixed portion) 112 is fixedly attached to a lower surface of the electrode flange 104 facing the shower plate 105.

The vertical plate surface portion (wall portion) 113 is provided to stand toward the shower plate 105 from the entire circumference of an outer end portion of an outline of the upper plate surface portion (fixed portion) 112.

The lower plate surface portion (base portion) 114 extends substantially parallel to the upper plate surface portion (fixed portion) 112 from a lower end of the vertical plate surface portion (wall portion) 113.

The electrode frame 110 is formed to have a U-shape in a cross-sectional shape perpendicular to an outline of the shower plate 105 by the upper plate surface portion (fixed portion) 112, the vertical plate surface portion (wall portion) 113, and the lower plate surface portion (base portion) 114. The electrode frame 110 is formed to have an internal space inside the U-shape by the upper plate surface portion (fixed portion) 112, the vertical plate surface portion (wall portion) 113, and the lower plate surface portion (base portion) 114.

The upper plate surface portion (fixed portion) 112 is attached to the circumferential wall 104b of the electrode flange 104 using the support member 111 such as a bolt. The support member 111 penetrates through the upper plate surface portion (fixed portion) 112.

The upper plate surface portion (fixed portion) 112 is positioned on the circumferential wall 104b side of the electrode flange 104 in the electrode frame 110, that is, on a low temperature side. As shown in FIGS. 3 and 4, the upper plate surface portion (fixed portion) 112 includes a notch 112a having a predetermined shape formed at an end portion (inner end of the outline) toward a center side of the gas introduction space 101b.

The notch 112a is formed on an opposite side of the insulating shield 106 and prevents deformation of the electrode frame 110 when a temperature of the electrode frame 110 is raised or lowered.

As shown in FIGS. 3 and 4, the notch 112a may be formed in, for example, an arc shape or a curved shape in a plan view. At a portion in which the notch 112a is provided, a length in a width direction of the electrode frame 110 in the upper plate surface portion (fixed portion) 112 becomes small. The notch 112a can be provided close to a corner portion of the shower plate 105 having a rectangular shape.

The vertical plate surface portion (wall portion) 113 is provided to stand substantially vertically toward a main surface of the shower plate 105 from the electrode flange 104. An upper end of the vertical plate surface portion (wall portion) 113 is connected to an end portion of the upper plate surface portion (fixed portion) 112 over the entire outer circumference of an outline of the electrode frame 110.

The vertical plate surface portion (wall portion) 113 is disposed on an inward side of the insulating shield 106. The vertical plate surface portion (wall portion) 113 faces an inner circumferential surface of the insulating shield 106.

An outer circumferential surface of a circumferential edge portion of the vertical plate surface portion (wall portion) 113 is spaced apart from the inner circumferential surface of the insulating shield 106. A gap 106b is formed between the outer circumferential surface of the circumferential edge portion of the vertical plate surface portion (wall portion) 113 and the inner circumferential surface of the insulating shield 106.

Here, the electrode frame 110 is attached to the electrode flange 104 and is a low temperature side. Therefore, thermally expanded lengths of the electrode frame 110 expected when a temperature is raised are smaller than thermally expanded lengths of the shower plate 105 and the slide plate 120 expected when a temperature is raised.

Therefore, the gap 106b is set to be smaller than the thermal expansion absorption space 106a. That is, a distance between an outer circumferential surface of the vertical plate surface portion (wall portion) 113 and the inner circumferential surface of the insulating shield 106 is set to be smaller than a distance between an outer circumferential end surface of the shower plate 105 and the inner circumferential surface of the insulating shield 106.

A step is formed on the inner circumferential surface of the insulating shield 106 to correspond to the gap 106b and the thermal expansion absorption space 106a. The step is formed on the electrode frame 110 side with respect to a sliding seal surface 114a and a sliding seal surface 120a which are contact positions between the slide plate 120 and the electrode frame 110.

The lower end of the vertical plate surface portion (wall portion) 113 is connected to an end portion on an outer circumferential side of the lower plate surface portion (base portion) 114.

The lower plate surface portion (base portion) 114 is disposed toward the center side of the gas introduction space 101b from the lower end of the vertical plate surface portion (wall portion) 113. That is, the lower plate surface portion (base portion) 114 extends toward an inward side of the outline of the electrode frame 110 from the lower end of the vertical plate surface portion (wall portion) 113. The lower plate surface portion (base portion) 114 extends parallel to the upper plate surface portion (fixed portion) 112.

The lower plate surface portion (base portion) 114 is on a high temperature side compared to the upper plate surface portion (fixed portion) 112. Therefore, a notch that prevents deformation is not provided. The lower plate surface portion (base portion) 114 has substantially the same width over the entire circumference of the shower plate 105.

A plate thickness of the lower plate surface portion (base portion) 114 can be set to be larger than a plate thickness of the upper plate surface portion (fixed portion) 112.

A lower surface of the lower plate surface portion (base portion) 114 on the shower plate 105 side is the sliding seal surface 114a that is parallel to the main surface of the shower plate 105.

The sliding seal surface 114a is in contact with the sliding seal surface 120a provided on an upper surface of the slide plate 120.

The sliding seal surface 114a is an entire region of the lower surface of the lower plate surface portion (base portion) 114 on the shower plate 105 side.

The stepped bolt 121 is screwed to the lower plate surface portion (base portion) 114 from below.

As shown in FIG. 3, a plate-shaped reflector 117 is provided on an inner circumferential side of the electrode frame 110 over the entire circumference thereof. The reflector 117 is provided at four locations parallel to outline sides of the shower plate 105 having a rectangular outline. The reflector 117 is disposed close to the inner circumferential side of the electrode frame 110.

The reflector 117 is a metal plate bent in an L shape. An upper end of the reflector 117 is bent to the center side of the gas introduction space 101b. A portion bent at the upper end of the reflector 117 is attached to the circumferential wall 104b of the electrode flange 104 using a screw 117a. An outward side of the upper end of the reflector 117 is disposed close to an inner distal end of the upper plate surface portion (fixed portion) 112 of the electrode frame 110.

A lower end of the reflector 117 is positioned close to an inner end of the lower plate surface portion (base portion) 114 of the electrode frame 110.

Therefore, the reflector 117 is disposed to face an opening of the internal space of the electrode frame 110 which is U-shaped in a cross-sectional view. Furthermore, the lower end of the reflector 117 and the inner end of the lower plate surface portion (base portion) 114 of the electrode frame 110 are not connected.

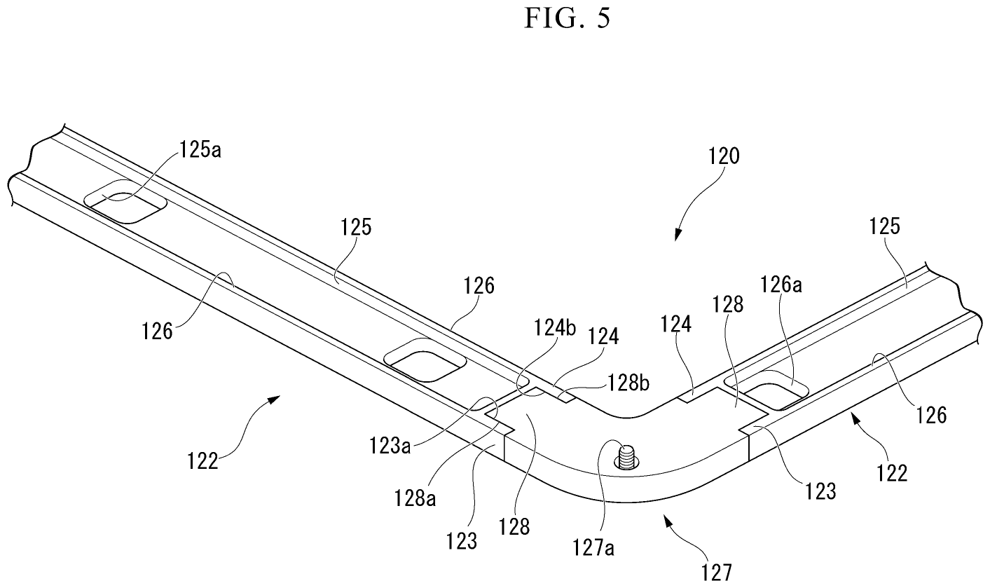

FIG. 5 is an enlarged perspective view showing a corner portion on a lower surface side of the slide plate 120 in the present embodiment.

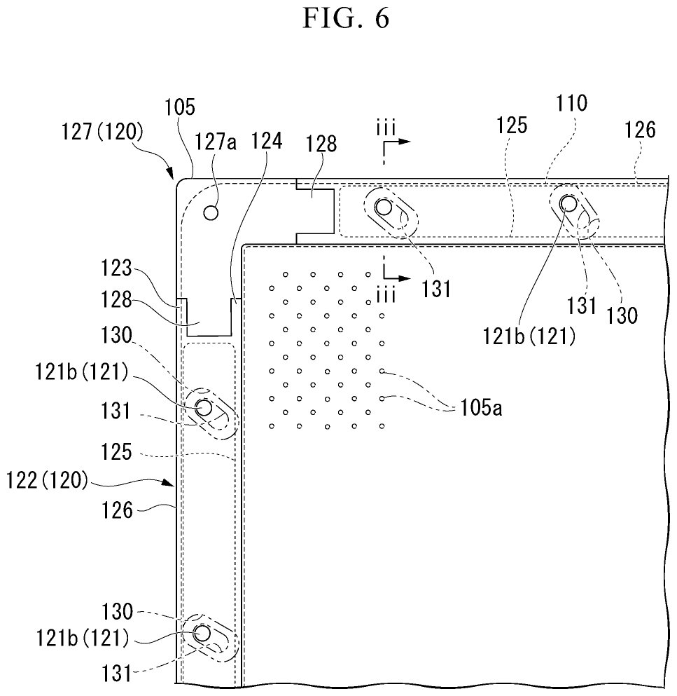

FIG. 6 is a bottom view showing a vicinity of a region including a circumferential edge portion of the shower plate 105 in the present embodiment.

An entire region of the upper surface of the slide plate 120 is the sliding seal surface 120a.

As shown in FIGS. 2 to 6, the slide plate 120 has a configuration in which a plate body thereof parallel to an upper surface of the shower plate 105 is formed in a frame shape having substantially the same width.

As shown in FIGS. 5 and 6, the slide plate 120 includes side slide portions 122 positioned corresponding to four sides of the shower plate 105 having substantially a rectangular outline, and corner slide portions 127 positioned corresponding to four corners (corners) of the shower plate 105.

The side slide portions 122 and the corner slide portions 127 have the same thickness as shown in FIG. 6. The side slide portions 122 and the corner slide portions 127 are all attached to the upper surface of the shower plate 105.

Each of the corner slide portions 127 is combined with end portion sides of the side slide portions 122 extending along two adjacent sides of the shower plate 105.

The corner slide portion 127 is fixed to the upper surface of the shower plate 105 using a fastening screw 127a.

The side slide portion 122 is attached to the upper surface of the shower plate 105 by being sandwiched between the corner slide portion 127 fixed to the shower plate 105, and the shower plate 105 and the electrode frame 110. Also, the side slide portion 122 is restricted in position not to come off also by the stepped bolt 121 penetrating through a through hole 125a as will be described below.

The corner slide portion 127 includes two labyrinth protrusions 128 and 128 protruding respectively toward the side slide portions 122 combined therewith. The labyrinth protrusions 128 each protrude in a direction along the outline side of the shower plate 105.

The two labyrinth protrusions 128 of the corner slide portion 127 protrude in directions perpendicular to each other. Each of the labyrinth protrusions 128 is disposed at a center in a width direction of the corner slide portion 127. That is, each of the two labyrinth protrusions 128 is disposed at a central position in a width direction of the slide plate 120 facing thereto.

Each of the side slide portions 122 includes two labyrinth protrusions 123 and 124 protruding toward the corner slide portion 127 combined therewith. The labyrinth protrusion 123 and the labyrinth protrusion 124 protrude in a direction along the outline side of the shower plate 105. The labyrinth protrusion 123 and the labyrinth protrusion 124 are formed parallel to each other.

The labyrinth protrusion 123 and the labyrinth protrusion 124 are respectively disposed at both outer positions in the width direction of the slide plate 120 with respect to the labyrinth protrusion 128 of the corner slide portion 127. The labyrinth protrusions 123 and the labyrinth protrusions 124 are set to have the same length in the width direction of the slide plate 120 as each other.

In the width direction of the slide plate 120, the widths of the labyrinth protrusion 123 and the labyrinth protrusion 124 can each be set to be smaller than the width of the labyrinth protrusion 128.

The labyrinth protrusion 123 and the labyrinth protrusion 128 are in contact with each other. Also, the labyrinth protrusion 124 and the labyrinth protrusion 128 are in contact with each other.

An inner side surface of the labyrinth protrusion 123 is a sliding seal surface 123a, and an outer side surface of the labyrinth protrusion 128 is a sliding seal surface 128a. The sliding seal surface 123a and the sliding seal surface 128a are in contact with each other.

An outer side surface of the labyrinth protrusion 124 is a sliding seal surface 124b, and an inner side surface of the labyrinth protrusion 128 is a sliding seal surface 128b. The sliding seal surface 124b and the sliding seal surface 128b are in contact with each other.

Here, in the labyrinth protrusions 123, 124, and 128, “inner side” and “outer side” indicate positions in inward and outward directions with respect to the gas introduction space 101b, that is, positions in a radial direction from a center in a plane of the shower plate 105.

In the labyrinth protrusion 128 provided on one side of the corner slide portion 127, the sliding seal surface 128a and sliding seal surface 128b are formed parallel to each other.

Also, in the two protrusions of the labyrinth protrusion 123 and the labyrinth protrusion 124 provided at one end of the side slide portion 122, the sliding seal surface 123a and the sliding seal surface 124b facing each other are formed parallel to each other.

The sliding seal surface 128a, the sliding seal surface 128b, the sliding seal surface 123a, and the sliding seal surface 124b are all formed in a direction parallel to the outline side of the shower plate 105.

The sliding seal surface 128a, the sliding seal surface 128b, the sliding seal surface 123a, and the sliding seal surface 124b are all formed in a vertical direction.

Upper ends of the sliding seal surface 128a, the sliding seal surface 128b, the sliding seal surface 123a, and the sliding seal surface 124b are all in contact with the electrode frame 110. Lower ends of the sliding seal surface 128a, the sliding seal surface 128b, the sliding seal surface 123a, and the sliding seal surface 124b are all in contact with the shower plate 105.

As described above, the labyrinth protrusion 123 of the side slide portion 122, the labyrinth protrusion 128 of the corner slide portion 127, and the labyrinth protrusion 124 of the side slide portion 122 are aligned in an outline direction of the gas introduction space 101b.

That is, the labyrinth protrusion 123, the labyrinth protrusion 128, and the labyrinth protrusion 124 are alternately disposed in the outline direction of the gas introduction space 101b to be multiple stages from an inner side toward an outer side of the gas introduction space 101b.

Therefore, even when the side slide portion 122 and the corner slide portion 127 relatively move in a direction parallel to the outline side of the shower plate 105, the labyrinth protrusion 124 and the labyrinth protrusion 128 are maintained in a state of being in contact with each other.

Since the sliding seal surface 124b and the sliding seal surface 128b are not spaced apart from each other in this manner, sealing at this portion is maintained.

At the same time, even when the side slide portion 122 and the corner slide portion 127 relatively move in a direction parallel to the outline side of the shower plate 105, the labyrinth protrusion 128 and the labyrinth protrusion 123 are maintained in a state of being in contact with each other.

Since the sliding seal surface 128a and the sliding seal surface 123a are not spaced apart from each other in this manner, sealing at this portion is maintained.

Furthermore, the labyrinth protrusion 128 of the corner slide portion 127 slides while being sandwiched between the labyrinth protrusion 123 and the labyrinth protrusion 124 of the side slide portions 122 positioned on both sides thereof.

Therefore, the sliding seal surface 124b and the sliding seal surface 128b are not spaced apart from each other. At the same time, the sliding seal surface 128a and the sliding seal surface 123a are not spaced apart from each other.

In this way, the side slide portion 122 and the corner slide portion 127 are slidable via the sliding seal surfaces 123a to 128b in response to thermal deformation that occurs when a temperature of the shower plate 105 is raised or lowered while a sealed state is maintained.

Therefore, with such a configuration, a sealed state in a side wall portion of the gas introduction space 101b can be maintained at a height position of the slide plate 120 regardless of a temperature state.

As shown in FIGS. 3, 5, and 6, the slide plate 120 includes a recessed groove 125 formed at a portion in contact with the shower plate 105, that is, on a lower surface of the slide plate 120.

The recessed groove 125 is formed such that a leg portion 126 in contact with the shower plate 105 is positioned on the entire circumference of the side slide portion 122.

A depth of the recessed groove 125 can be freely set as long as the depth is smaller than a thickness of the slide plate 120 and is of a magnitude such that a strength of the slide plate 120 does not deteriorate.

A width of the leg portion 126, that is, a length in a width direction of the slide plate 120 is preferably as small as possible as long as it is of a magnitude such that a strength of the slide plate 120 does not deteriorate.

When the recessed groove 125 is formed, an area of the slide plate 120 in contact with the shower plate 105 can be made small. Therefore, a cross-sectional area of a heat transfer path from the shower plate 105 toward the slide plate 120 can be made small.

In the present embodiment, the recessed groove 125 is formed on the side slide portion 122. Furthermore, the recessed groove can be formed also on the corner slide portion 127.

In this case, as in the side slide portion 122, the recessed groove can be formed such that a leg portion in contact with the shower plate 105 is positioned on the entire circumference of the corner slide portion 127. Furthermore, in this case, the recessed groove can be formed also on the labyrinth protrusion 128 in the corner slide portion 127.

The through hole 125a is provided inside the recessed groove 125. The through hole 125a penetrates through the slide plate 120. A plurality of through holes 125a are provided in a direction in which the side slide portion 122 extends. The plurality of through holes 125a are disposed to be spaced apart from each other.

The stepped bolt 121 penetrates through each of the through holes 125a.

A diameter of the through hole 125a is set to be larger than a diameter of the stepped bolt 121. An outline shape of the through hole 125a corresponds to an elongated hole 131 to be described below.

Here, “shape of the through hole 125a corresponding to the elongated hole 131” indicates that, as will be described below, a shaft portion 121b of the stepped bolt 121 has a shape that is slidable without any trouble in response to thermal deformation that occurs when a temperature of the shower plate 105 is raised or lowered. That is, it indicates that the through hole 125a has a shape that does not affect relative movement of the stepped bolt 121 inside the elongated hole 131.

Specifically, the diameter of the through hole 125a is larger than a length of a major axis of the elongated hole 131. That is, when the through hole 125a is formed to be larger than the elongated hole 131 in a plan view, the through hole 125a does not come into contact with the shaft portion 121b of the stepped bolt 121 that relatively moves inside the elongated hole 131.

Furthermore, the outline shape of the through hole 125a is not particularly limited as long as it has the above lengths.

As shown in FIGS. 3 and 6, a lower surface of the shower plate 105 includes a suspending groove 130 provided at the circumferential edge portion of the shower plate 105.

A plurality of suspending grooves 130 are provided in the circumferential edge portion of the shower plate 105 at predetermined intervals.

The elongated hole 131 penetrating through the shower plate 105 in a thickness direction is provided inside each of the suspending grooves 130.

The suspending groove 130 is formed as an enlarged shape of the elongated hole 131.

As shown in FIGS. 3 and 6, the shaft portion 121b of the stepped bolt 121 penetrates through the elongated hole 131 and is fixed to the electrode frame 110.

The elongated hole 131 is formed to be longer in the direction of thermal deformation that occurs when a temperature of the shower plate is raised or lowered so that the shaft portion 121b of the stepped bolt 121 is slidable in response to the thermal deformation that occurs when a temperature of the shower plate 105 is raised or lowered.

That is, the elongated hole 131 has the major axis parallel to a straight line drawn radially from the fixed shaft 109 which is at a central position of the shower plate 105 in a plan view. Therefore, the elongated hole 131 is an ellipse (rounded rectangle) having a major axis with a different inclination direction depending on a disposition position thereof.

The elongated hole 131 has an opening size in a major axis direction set to be longer than a distance over which the shaft portion 121b of the stepped bolt 121 relatively moves in response to thermal deformation that occurs when a temperature of the shower plate 105 is raised or lowered. Therefore, a length of the elongated hole 131 in the major axis direction needs to be appropriately changed according to a length of the shower plate 105 and a coefficient of thermal expansion defined by a material thereof.

An opening size of the elongated hole 131 in a minor axis direction may be slightly larger than an outer diameter of the shaft portion 121b of the stepped bolt 121.

A long slide member (long washer) 132 is disposed in an opening of the elongated hole 131 on the suspending groove 130 side. The shaft portion 121b of the stepped bolt 121 penetrates through the long slide member 132.

The long slide member 132 has an outline shape having a similar shape to the suspending groove 130 and has the same or slightly smaller lengths than those of the suspending groove 130. The long slide member 132 has an opening shape having a similar shape to the elongated hole 131 and has the same or slightly smaller lengths than those of the elongated hole 131.

A diameter of the opening of the long slide member 132 in the minor axis direction is set to be the same as or slightly smaller than a diameter of the opening of the elongated hole 131 in the minor axis direction. A diameter of the opening of the long slide member 132 in the major axis direction is set to be the same as or slightly smaller than a diameter of the opening of the elongated hole 131 in the major axis direction.

A bolt head 121a of the stepped bolt 121 is positioned below the long slide member 132. A slide member (washer) 133 and disc springs 134 and 135 are disposed to be stacked from above between the long slide member 132 and the bolt head 121a.

The shaft portion 121b of the stepped bolt 121 penetrates through the slide member 133 and the disc springs 134 and 135.

The diameter of the opening of the long slide member 132 in the minor axis direction is set to be smaller than an outer diameter of the bolt head 121a of the stepped bolt 121.

Also, the diameter of the opening of the long slide member 132 in the minor axis direction is set to be smaller than an outer diameter of the slide member 133.

The outer diameter of the slide member 133 is set to be the same as or slightly larger than the outer diameter of the bolt head 121a. Also, the outer diameter of the slide member 133 is set to be larger than the diameter of the opening of the long slide member 132 in the minor axis direction.

Inner diameters of the slide member 133 and the disc springs 134 and 135 are set to be the same as or slightly larger than the outer diameter of the shaft portion 121b of the stepped bolt 121.

The slide member 133 and the disc springs 134 and 135 follow sliding of the stepped bolt 121 which is slidable inside the suspending groove 130.

The long slide member 132 and the slide member 133 are slidably in contact with each other.

When the shaft portion 121b of the stepped bolt 121 relatively moves in the major axis direction of the elongated hole 131 inside the suspending groove 130 in response to the slide plate 120 that slides due to thermal deformation that occurs when a temperature of the shower plate 105 is raised or lowered, the slide member 133 also slides in the major axis direction of the elongated hole 131 inside the suspending groove 130 according to the relative movement.

At this time, the slide member 133 slides with the long slide member 132 positioned below a circumference of the elongated hole 131 inside the suspending groove 130.

At this time, a relationship between the size of the opening of the elongated hole 131 in the minor axis direction, the size of the opening of the long slide member 132 in the minor axis direction, the outer diameter of the slide member 133, and the outer diameter of the bolt head 121a, in order from the above, is set as described above.

Therefore, the long slide member 132 can be restricted such that it does not move from the opening of the elongated hole 131 to the recessed groove 125 side. The slide member 133 can be restricted such that it does not move from the opening of the long slide member 132 to the recessed groove 125 side. The bolt head 121a can be restricted such that it does not move in a vertical direction with respect to the slide member 133.

Therefore, a position of the bolt head 121a is restricted such that it does not move to the electrode frame 110 side by the long slide member 132 and the slide member 133.

That is, the bolt head 121a of the stepped bolt 121 can be restricted such that it does not come off to the recessed groove 125 side.

Therefore, the long slide member 132 and the slide member 133 restrict the position of the bolt head 121a to be constant in an axial direction of the stepped bolt 121.

That is, the long slide member 132 and the slide member 133 slide while a suspended state of the shower plate 105 due to the stepped bolt 121 is maintained. Therefore, a suspended height position of the shower plate 105 is maintained, and the stepped bolt 121 is slidable inside the suspending groove 130.

The long slide member 132 and the slide member 133 can be made of the same material as the slide plate 120. Specifically, the long slide member 132 and the slide member 133 can be made of a metal such as Hastelloy.

The disc springs 134 and 135 are attached to apply a force to the bolt head 121a of the stepped bolt 121 downward.

Similarly to the slide member 133, the disc springs 134 and 135 are movable according to the sliding movement of the shaft portion 121b of the stepped bolt 121 inside the suspending groove 130 in response to thermal deformation that occurs when a temperature of the shower plate 105 is raised or lowered. At this time, a state of applying a force to the bolt head 121a and the slide member 133 by the disc springs 134 and 135 is maintained.

Furthermore, a plurality of disc springs 134 and 135 may be provided, and the number thereof is not limited. The slide member 133 and the disc springs 134 and 135 can be made of a material having elasticity such as, for example, Inconel (registered trademark).

A lid 136 is provided at a position at a lower side opening of the suspending groove 130. The lower side opening of the suspending groove 130 is closed by the lid 136. The lid 136 on the opening side of the suspending groove 130 is coplanar with the lower surface of the shower plate 105. Alternatively, the opening side of the suspending groove 130 can be positioned slightly below the lower surface of the shower plate 105.

In FIG. 6, illustrations of the long slide member 132, the slide member 133, the disc springs 134 and 135, and the lid 136 are omitted. Also, in FIG. 6, main portions such as the slide plate 120 and the electrode frame 110 are shown by broken lines.

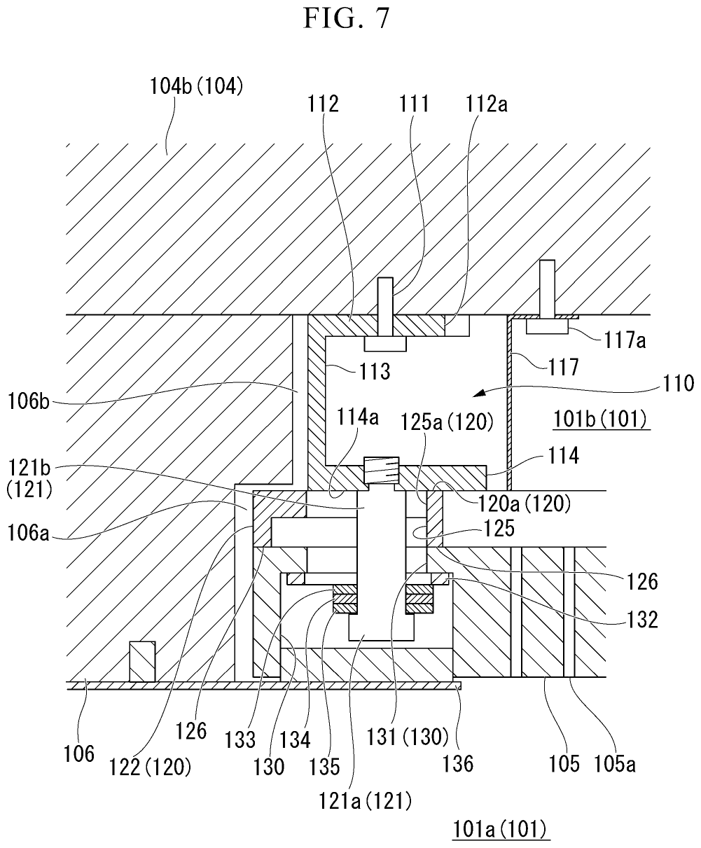

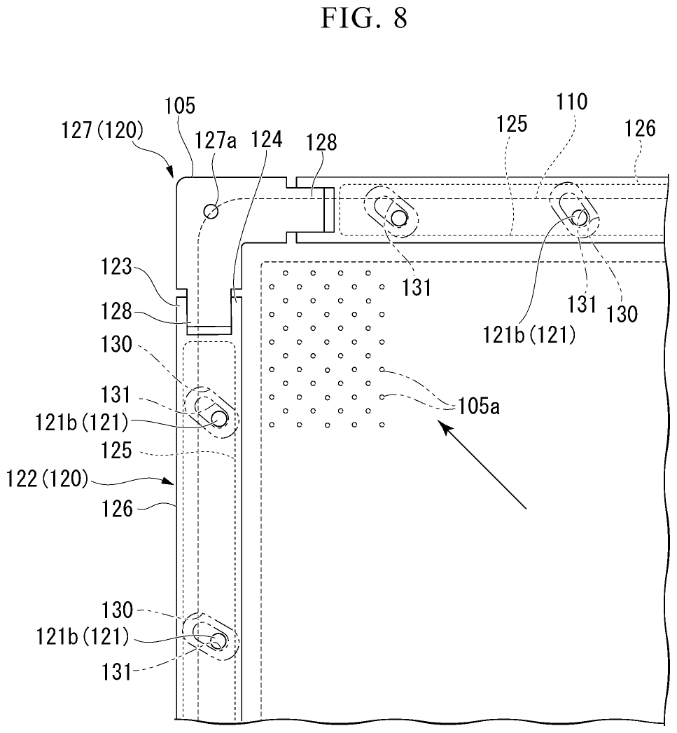

FIG. 7 is an enlarged cross-sectional view showing a vicinity of an edge portion of the shower plate 105 in a thermally expanded state of the present embodiment. FIG. 8 is a bottom view showing a region including a circumferential edge portion of the shower plate 105 in the thermally expanded state of the present embodiment.

When the apparatus is used as will be described below, since the apparatus is heated, the shower plate 105 is thermally expanded (thermally deformed). At the time of the thermal expansion, as shown by an arrow in FIGS. 7 and 8, the shower plate 105 expands outward in an in-plane direction with the fixed shaft 109 as a center.

The circumferential edge portion of the thermally expanded shower plate 105 expands in the thermal expansion absorption space 106a and thus does not come into contact with the insulating shield 106. Therefore, expansion of the shower plate 105 is absorbed such that stress is not applied to the electrode flange 104, the electrode frame 110, the insulating shield 106, or the like.

At this time, the movable shafts 108 can support the deformed shower plate 105 due to the spherical bushes at the lower ends.

Furthermore, the slide plate 120 fixed to the circumferential edge portion of the thermally expanded shower plate 105 integrally moves outward of the outer circumference of the shower plate 105. At this time, the circumferential edge portion of the shower plate 105 and the slide plate 120 also move to narrow the thermal expansion absorption space 106a (see FIG. 7) as shown by the arrow in FIG. 8.

Since the slide plate 120 does not come into contact with the insulating shield 106, movement of the slide plate 120 is absorbed such that stress is not applied to the electrode flange 104, the electrode frame 110, the insulating shield 106, or the like.

Also, along with the movement of the slide plate 120 outward of the outer circumference of the shower plate 105, the slide plate 120 and the shower plate 105 integrally move outward of the outer circumference of the shower plate 105. In contrast, since the electrode frame 110 is fixed to the electrode flange 104, a relative position thereof with respect to the electrode flange 104 and the insulating shield 106 does not change that much.

Therefore, the sliding seal surface 114a of the electrode frame 110 and the sliding seal surface 120a of the slide plate 120 slide with each other while the electrode frame 110 is not deformed, and thus the shower plate 105 is in a thermally expanded state while a sealed state is maintained.

At this time, the stepped bolt 121 is fixed to the electrode frame 110. Therefore, a relative position of the stepped bolt 121 with respect to the electrode flange 104 and the insulating shield 106 does not change that much.

Also, the elongated hole 131 and the suspending groove 130 also move outward of the outer circumference of the shower plate 105 in the circumferential edge portion of the shower plate 105.

Therefore, the stepped bolt 121 relatively moves in the major axis direction of the elongated hole 131.

In the present embodiment, the major axis direction of the elongated hole 131 coincides with the direction of thermal deformation that occurs when a temperature of the shower plate 105 is raised or lowered. Therefore, the shaft portion 121b of the stepped bolt 121 is slidable inside the elongated hole 131 in response to thermal deformation that occurs when a temperature of the shower plate 105 is raised or lowered.

Therefore, movement of the stepped bolt 121 is absorbed such that stress is not applied to the shower plate 105 and the stepped bolt 121 which are positioned close to the elongated hole 131.

Also, the through hole 125a of the slide plate 120 also moves outward of the outer circumference of the shower plate 105 with respect to the stepped bolt 121.

Therefore, the stepped bolt 121 moves relative to the through hole 125a.

Since the through hole 125a has a shape corresponding to the elongated hole 131, the shaft portion 121b of the stepped bolt 121 is slidable inside the through hole 125a in response to thermal deformation that occurs when a temperature of the shower plate 105 is raised or lowered. Therefore, movement of the stepped bolt 121 is absorbed such that stress is not applied to the slide plate 120 and the stepped bolt 121 which are positioned close to the through hole 125a.

Therefore, suspending support of the shower plate 105 with respect to the electrode frame 110 by the stepped bolt 121 is maintained.

In the present embodiment, the sliding seal surface 114a of the lower plate surface portion (base portion) 114 of the electrode frame 110 and the sliding seal surface 120a of the slide plate 120 can slide with each other in a thermal expansion direction of the shower plate 105. Therefore, even during the thermal expansion, a contact state therebetween is maintained without being deformed, and therefore a sealed state and a state of supporting a load of the shower plate 105 can be maintained.

Also, since the electrode frame 110 and the slide plate 120 are made of the same material of Hastelloy, generation of particles due to scratching between the members can be suppressed.

Therefore, deterioration of film thickness characteristics in the vacuum processing apparatus 100 can be prevented.

Furthermore, in the present embodiment, the corner slide portion 127 that slidably seals end portions of the side slide portions 122 of the slide plate 120 is provided at positions of corner portions (corner portions) of the upper surface of the shower plate 105 having a rectangular outline shape.

In the circumferential edge portion of the thermal expanded shower plate 105, the side slide portion 122 and the corner slide portion 127 which are fixed to the circumferential edge portion of the shower plate 105 are spaced apart in a linear direction along the outline side of the shower plate 105.

Therefore, the labyrinth protrusion 123 and the labyrinth protrusion 124 of the side slide portion 122 and the labyrinth protrusion 128 of the corner slide portion 127 are spaced apart from each other.

At this time, the sliding seal surface 123a and the sliding seal surface 128a, and the sliding seal surface 124b and the sliding seal surface 128b slide respectively in a direction along a straight line of the outline side of the shower plate 105, and therefore the side slide portion 122 and the corner slide portion 127 can be spaced apart from each other while the sealed state is maintained.

Gas leakage in the shower plate 105 can be prevented by the side slide portion 122 and the corner slide portion 127 having the labyrinth structure as described above, and therefore a sealed state of the gas introduction space 101b can be maintained.

At the same time, when a temperature of the shower plate 105 is raised, heat escapes from the shower plate 105 on a high temperature side to the electrode flange 104 on a low temperature side.

Here, in the slide plate 120 serving as a heat transfer path, the leg portion 126 is in contact with the shower plate 105.

However, the recessed groove 125 is formed on the slide plate 120, and a portion corresponding to the recessed groove 125 is not in contact with the shower plate 105. Therefore, the heat transfer path is reduced by an area corresponding to the recessed groove 125. Therefore, an amount of heat conducted from the shower plate 105 to the slide plate 120 is reduced.

Similarly, in the electrode frame 110 serving as a heat transfer path, the lower surface of the lower plate surface portion (base portion) 114 is in contact with the slide plate 120 on a high temperature side. However, in the electrode frame 110, a portion extending in the vertical direction is the vertical plate surface portion (wall portion) 113 and an internal space having a U-shaped cross section is formed.

Therefore, a portion corresponding to a plate thickness of the vertical plate surface portion (wall portion) 113 serves as the heat transfer path with respect to an area of the lower plate surface portion (base portion) 114. Therefore, the heat transfer path is reduced by an area corresponding to the U-shaped internal space of the electrode frame 110. Therefore, an amount of heat conducted from the slide plate 120 to the electrode flange 104 is reduced.

Therefore, heat insulation between the electrode frame 110 and the slide plate 120 can be improved.

At the same time, a heat flux in a path from the shower plate 105 to the circumferential wall 104b of the electrode flange 104 via the slide plate 120 and the electrode frame 110 can be reduced.

Therefore, deterioration of a temperature distribution in the shower plate 105 can be prevented by reducing a temperature drop in the circumferential edge of the shower plate 105.

Therefore, it is possible to prevent deterioration of a film thickness distribution and improve film thickness characteristics in the vacuum processing apparatus 100.

Next, a case in which a film is formed on a processing surface of the substrate S using the vacuum processing apparatus 100 will be described.

First, the inside of the vacuum chamber 102 is depressurized using the vacuum pump 148. In a state in which the inside of the vacuum chamber 102 is maintained at a vacuum, the substrate S is loaded from the outside of the vacuum chamber 102 toward the deposition space 101a. The substrate S is placed on the support portion (heater) 141.

The support column 145 is pushed upward, and the substrate S placed on the support portion (heater) 141 also is moved upward. Therefore, a distance between the shower plate 105 and the substrate S is determined as desired to be a distance needed for performing appropriate film deposition, and then the distance is maintained.

Thereafter, a process gas is introduced from the gas supply unit 142 into the gas introduction space 101b through a gas introduction pipe and a gas introduction port. Then, the process gas is ejected from the gas ejection ports 105a of the shower plate 105 into the film deposition space 101a.

Next, the RF power supply 147 is activated to apply high-frequency power to the electrode flange 104.

Then, a high-frequency current flows from a surface of the electrode flange 104 along the surface of the shower plate 105, and electrical discharge is generated between the shower plate 105 and the support portion (heater) 141.

Then, a plasma is generated between the shower plate 105 and the processing surface of the substrate S.

The process gas is decomposed in the plasma generated as described above so that a process gas in a plasma state can be obtained, vapor phase epitaxy reactions occur on the processing surface of the substrate S, and therefore a thin film is deposited on the processing surface.

During the processing of the vacuum processing apparatus 100, although the shower plate 105 is thermally expanded (thermally deformed), a sealed state is maintained by the electrode frame 110 and the slide plate 120, and leakage from the gas introduction space 101b to the film deposition space 101a through a portion other than the gas ejection ports 105a can be reduced. Also, since there is no component that is forced to be deformed by the thermal expansion of the shower plate 105, service lives of components can be prolonged.

Also, although the shower plate 105 is thermally contracted (thermally deformed) at the end of the processing of the vacuum processing apparatus 100, the sealed state is maintained by the electrode frame 110 and the slide plate 120, and leakage from the gas introduction space 101b to the film deposition space 101a through a portion other than the gas ejection ports 105a can be reduced. Also, since there is no component that is forced to be deformed by the thermal contraction of the shower plate 105, service lives of components can be prolonged.

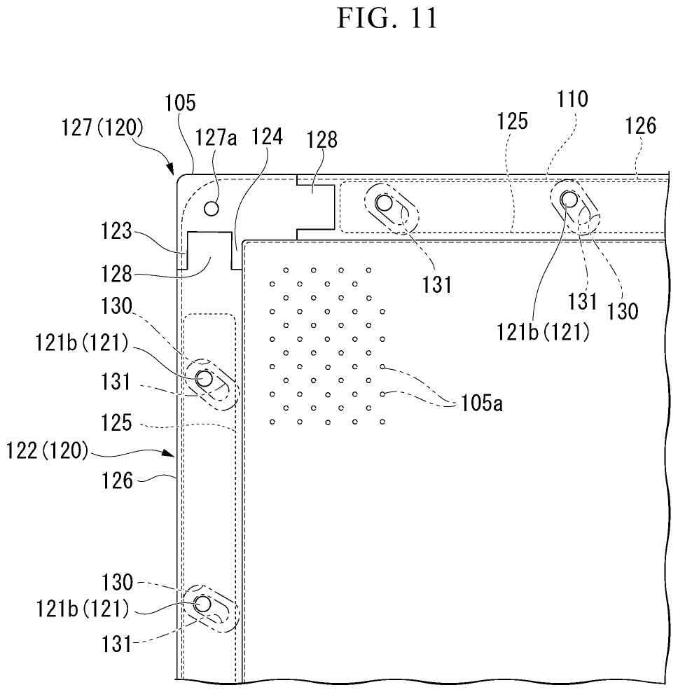

Furthermore, in the present embodiment, the corner slide portion 127 includes two labyrinth protrusions 128 and 128 protruding respectively toward the side slide portions 122 combined thereto, but, as shown in FIG. 11, the protruding labyrinth protrusion 128 may be provided on the side slide portion 122 toward the corner slide portion 127.

Also in this configuration, the side slide portion 122 and the corner slide portion 127 can slide in response to thermal deformation that occurs when a temperature of the shower plate 105 is raised or lowered while a sealed state is maintained.

Furthermore, in FIG. 11, the labyrinth protrusion 128 is disposed on only one side of the side slide portion 122, but the labyrinth protrusion 128 can be disposed on both sides of the side slide portion 122.

### EXAMPLE

Examples according to the present invention will be described below.

As a specific example of the vacuum processing apparatus in the present invention, a simulation of film thickness distribution at the time of film deposition will be described.

### Experimental Example 1

In the vacuum processing apparatus 100 of the above-described embodiment, film deposition of an oxide film, particularly film deposition of SiOₓ using tetraethyl orthosilicate (TEOS) having a large molecular weight as a source gas was examined.

Parameters in the film deposition processing of TEOS-SiOₓ are shown below.
Substrate heating temperature; 430° C.
Lengths of the substrate S to be processed; 1500×1800 mm
Width of the slide plate 120; 35 mm
Thickness of the slide plate 120; 10 mm
Depth of the recessed groove 125; 5 mm
Width of the leg portion 126; 3 mm
Height of the electrode frame 110; 32.5 mm
Thickness of the vertical plate surface portion 113; 3 mm

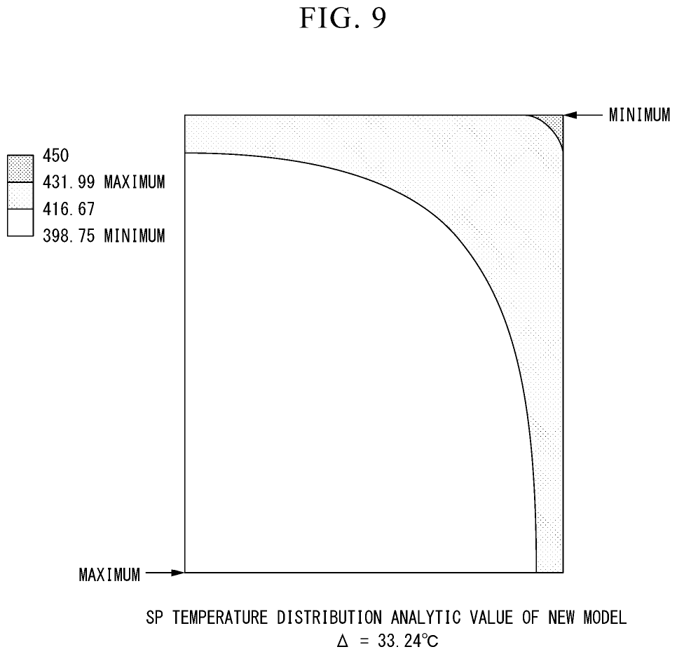

Simulation results of the temperature distribution in the shower plate is shown in FIG. 9.

A quarter of the shower plate is shown in FIG. 9. That is, a lower left is the center position of the shower plate.

From the results, it can be ascertained that a maximum temperature in the shower plate 105 is 431.99° C., a minimum temperature is 398.75° C., and an in-plane temperature distribution Δ=33.24° C. in the vacuum processing apparatus 100 of the embodiment described above.

### Experimental Example 2

As in Experimental example 1, a film deposition of SiOₓ using tetraethyl orthosilicate (TEOS) was examined.

Here, an apparatus in which the slide plate and the electrode frame in the above-described embodiment are integrally formed while the width is the same, and the electrode frame has a dense bulk structure without a recessed groove or a space is used.

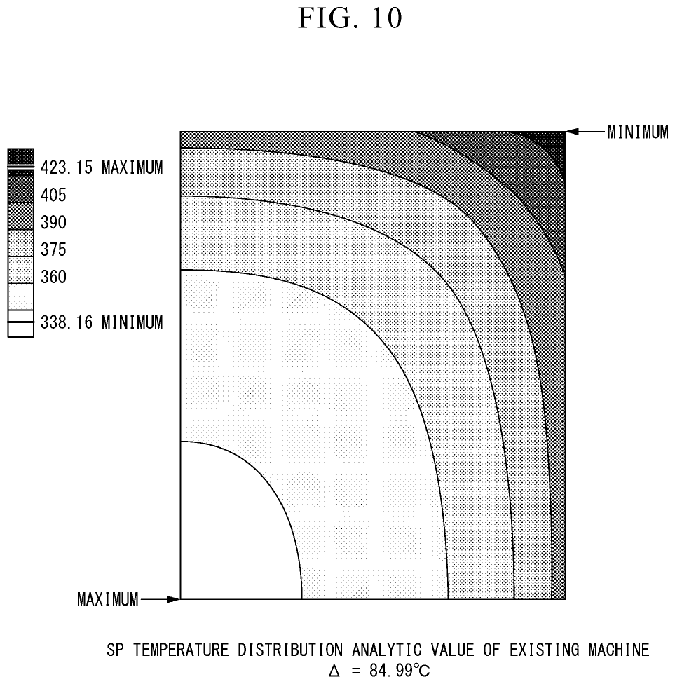

Simulation results of the temperature distribution in the shower plate is shown in FIG. 10.

In FIG. 10, a quarter of the shower plate is shown. That is, a lower left is the center position of the shower plate.

From the results, it can be ascertained that a maximum temperature in the shower plate is 423.15° C., a minimum temperature is 338.16° C., and an in-plane temperature distribution Δ=84.99° C. in the vacuum processing apparatus of Experimental example 2.

Furthermore, it can be ascertained that a stress distribution of SiN can be improved when the in-plane temperature distribution in the shower plate 105 is improved.

### INDUSTRIAL APPLICABILITY

As an application example of the present invention, as processing using a plasma, a plasma processing apparatus which performs a surface treatment on a substrate such as film deposition, particularly plasma CVD, or etching can be exemplified.

### DESCRIPTION OF REFERENCE NUMERALS

100 Vacuum processing apparatus

101 Processing chamber

101a Film deposition space

101b Space (gas introduction space)

102 Vacuum chamber

103 Insulating flange

104 Electrode flange

104a Upper wall (electrode flange)

104b Circumferential wall (electrode flange)

105 Shower plate

105a Gas ejection port

106 Insulating shield

106a Thermal expansion absorption space (gap)

106b Gap

108 Movable shaft

109 Fixed shaft

110 Electrode frame

111 Support member

112 Upper plate surface portion (fixed portion)

112a Notch

113 Vertical plate surface portion (wall portion)

114 Lower plate surface portion (base portion)

114a, 120a, 123a, 124b, 128a, 128b Sliding seal surface

117 Reflector

117a Screw

120 Slide plate

121 Stepped bolt (support member)

121a Bolt head

121b Shaft portion

122 Side slide portion

123, 124, 128 Labyrinth protrusion

125 Recessed groove

125a Through hole

126 Leg portion

127 Corner slide portion

127a Fastening screw

130 Suspending groove

131 Elongated hole

132 Long slide member (long washer)

133 Slide member (washer)

134, 135 Disc spring

136 Lid

141 Support portion (heater)

142 Gas supply unit (gas supply means)

145 Support column

147 RF power supply (high-frequency power supply)

148 Vacuum pump (evacuation means)

S Substrate (processing-target substrate)

What is claimed is:

1. A vacuum processing apparatus which performs plasma processing, the vacuum processing apparatus comprising:
an electrode flange connected to a high-frequency power supply;
a shower plate spaced apart from and facing the electrode flange and serving as a cathode together with the electrode flange;
an insulating shield provided around the shower plate;
a processing chamber in which a processing-target substrate is to be disposed in an opposite side of the shower plate opposite with respect to the electrode flange;
an electrode frame attached to the shower plate side of the electrode flange; and
a slide plate attached to a circumferential edge portion of the shower plate on the electrode frame side, wherein
the shower plate is formed to have a substantially rectangular outline,
the electrode frame and the slide plate are slidable in response to thermal deformation that occurs when a temperature of the shower plate is raised or lowered, and a space surrounded by the shower plate, the electrode flange, and the electrode frame is sealable, and
the electrode frame comprises:
a frame-shaped upper plate surface portion attached to the electrode flange;
a vertical plate surface portion provided to stand toward the shower plate from an entire outer circumference of an outline of the upper plate surface portion; and
a lower plate surface portion extending substantially parallel to the upper plate surface portion from a lower end of the vertical plate surface portion toward an inner end of the outline of the upper plate surface portion.

2. The vacuum processing apparatus according to claim 1, wherein
the slide plate has a recessed groove formed at a portion in contact with the shower plate.

3. The vacuum processing apparatus according to claim 1, wherein
the slide plate comprises:
a side slide portion corresponding to a side of the shower plate having a substantially rectangular outline; and
a corner slide portion corresponding to a corner of the shower plate, and wherein
the side slide portion and the corner slide portion are in contact with each other via a sliding seal surface which is parallel to the side of the shower plate, and
the side slide portion and the corner slide portion are slidable via the sliding seal surface in response to thermal deformation that occurs when a temperature of the shower plate is raised or lowered while a sealed state is maintained.

4. The vacuum processing apparatus according to claim 3, wherein
an upper end of the sliding seal surface is in contact with the electrode frame and a lower end of the sliding seal surface is in contact with the shower plate in the side slide portion and the corner slide portion.

5. The vacuum processing apparatus according to claim 1, wherein
a plate-shaped reflector along an entire circumference of the electrode frame is provided on an inner circumferential side of the electrode frame,
an upper end of the reflector is attached to the electrode flange, and
a lower end of the reflector is positioned close to an inner end of the lower plate surface portion.

6. The vacuum processing apparatus according to claim 1, wherein
the shower plate is supported by the electrode frame using a support member penetrating through an elongated hole provided in the shower plate, and
the elongated hole is formed to be longer in a direction of thermal deformation that occurs when a temperature of the shower plate is raised or lowered so that the support member is slidable with respect to the slide plate in response to the thermal deformation that occurs when a temperature of the shower plate is raised or lowered.

7. The vacuum processing apparatus according to claim 1, wherein
a gap which allows the shower plate to be thermally expandable is provided between circumferential end surfaces of the shower plate and the slide plate, and the insulating shield.
